(19) United States
(12) Patent Application Publication
(10) Pub. No.: US 2023/0006082 A1
(43) Pub. Date: Jan. 5, 2023

(54) HYBRID PHOTOVOLTAIC DEVICE HAVING RIGID PLANAR SEGMENTS AND FLEXIBLE NON-PLANAR SEGMENTS

(71) Applicant: SOLARPAINT LTD., YOKNEAM ILLIT (IL)

(72) Inventors: Eran MAIMON, Kibbutz Nahsholim (IL); Ramon Joseph ALBALAK, Haifa (IL); Oded ROZENBERG, Kibbutz Nahsholim (IL)

(21) Appl. No.: 17/802,335

(22) PCT Filed: Feb. 25, 2021
(86) PCT No.: PCT/IL2021/050217

§ 371 Date: Aug. 25, 2022

Related U.S. Application Data
(60) Provisional application No. 62/982,536, filed on Feb. 27, 2020.

(51) Int. Cl. H01L 31/048

(52) U.S. Cl. CPC H01L 31/0481; H01L 31/0504

(57) ABSTRACT

A hybrid photovoltaic (PV) device includes: a rigid PV segment, having one or more PV cells that convert light to electricity, wherein the rigid PV segment is non-foldable and non-bendable; a co-located flexible PV segment, wherein the flexible PV segment is foldable or bendable without being damaged; electric connectors, that connect between (i) electric current or voltage generated by the rigid PV segment, and (ii) electric current or voltage generated by the flexible PV segment; a unified encapsulation layer, encapsulating together both the rigid PV segment and the co-located flexible PV segment. The rigid PV segment, the co-located flexible PV segment, the electric connectors, and the unified encapsulation layer, form together the hybrid PV device as a single stand-alone PV device that converts light to electricity, and has at least one rigid region corresponding to the rigid PV segment and at least one flexible region corresponding to the co-located flexible PV segment.

### CROSS-REFERENCE TO RELATED APPLICATIONS

This patent application claims priority and benefit from U.S. 62/982,536, filed on Feb. 27, 2020, which is hereby incorporated by reference in its entirety.

### FIELD

Some embodiments are related to the field of photovoltaic (PV) cells and solar panels.

### BACKGROUND

The photovoltaic (PV) effect is the creation of voltage and electric current in a material upon exposure to light. It is a physical and chemical phenomenon.

The PV effect has been used in order to generate electricity from sunlight. For example, PV solar panels absorb sunlight or light energy or photons, and generate current electricity through the photovoltaic effect.

### SUMMARY

Some embodiments may include a combined or hybrid photovoltaic (PV) article, or a combined or hybrid PV device, or a combined or hybrid PV module, or a combined or hybrid electricity-generating PV device or PV article; as well as methods and systems for manufacturing such combined or hybrid PV device.

The combined or hybrid PV device may comprise, for example: (i) a first segment, which is a first electricity-generating PV segment that is planar and/or rigid; connected mechanically and/or electrically to (ii) a second, co-located, segment, which is a second electricity-generating PV segment that is flexible and/or non-planar and/or curved and/or angular; wherein the first electricity-generating PV segment and the second electricity-generating PV segment are encapsulated and/or enclosed and/or surrounded together within a single encapsulant, or within a single set of multiple encapsulating materials or encapsulation layers or encapsulation coatings; forming a single electricity-generating PV device, which may be monolithic (e.g., cannot be broken or separated or dis-assembled into smaller PV units; yet also, has sufficient flexibility in at least one region to allow at least that region to bend or to fold or to otherwise modify its spatial structure).

Some embodiments may provide other and/or additional benefits and/or advantages.

### BRIEF DESCRIPTION OF THE DRAWINGS

FIG. 1 is a schematic illustration of a photovoltaic (PV) device, in accordance with some demonstrative embodiments.

FIG. 2 is a schematic illustration of another PV device, in accordance with some demonstrative embodiments.

### DETAILED DESCRIPTION OF SOME DEMONSTRATIVE EMBODIMENTS

In accordance with some embodiments, solar modules or photovoltaic (PV) modules, or other surface-based electronic products (e.g., display units) may be divided or categorized according to their degree of flexibility and/or according to their level of flexibility and/or according to their level of elasticity and/or according to their level of rigidity or rigidness and/or according whether they have a planar structure or a non-planar (e.g., curved or angular) structure.

For example, a first electricity-generating PV unit or segment is rigid and planar, such that it has a spatial structure of a plane, without any curves or curvatures, and such that it has a high level of rigidity which does not allow it to be folded or rolled or bent; and such that an attempt to fold or curve such rigid PV unit by applying mechanical force(s) to it would typically cause breaking or damaging of such rigid PV unit.

For example, a second electricity-generating PV unit is flexible and/or non-planar; such that it may change its spatial structure, or may be bent or folded or rolled, or may become curved or partially-curved or non-planar or angular or partially-angular, in response to application of mechanical force(s); without such mechanical force(s) causing it to break or damaging it (e.g., at least while such mechanical force(s) are within a pre-defined range of forces that may be safely applied to the PV unit in order to safely modify its shape or structure or curvature without damaging it).

The Applicants have realized that such rigid and planar PV unit, while not being able to be bent or folded, typically has the highest efficiency in converting light or sunlight into electricity; relative to a curved or a non-planar PV unit, or relative to a flexible or non-rigid PV unit.

The Applicants have realized that it may be beneficial to provide a combined or hybrid PV device or PV article or PV unit; which includes, for example: (i) a first segment, which is a first electricity-generating PV segment that is planar and/or rigid; connected mechanically and/or electrically to a second segment, which is a second electricity-generating PV segment that is flexible and/or non-planar and/or curved and/or angular; wherein the first electricity-generating PV segment and the second electricity-generating PV segment are encapsulated and/or enclosed together within a single encapsulant, or within a single set of multiple encapsulating materials or encapsulation layers or encapsulation coatings; forming a single electricity-generating PV device.

Each solar segment or PV segment may comprise a semiconductor, such as silicon or other suitable substrate or material(s). For example, the underlying components of a PV segment are solar cells or a plurality of PV cells, formed of relatively large semiconductor wafers (e.g., formed of silicon wafers, or other suitable substrate or material), which may be very brittle (e.g., hard, but might break or shatter easily) and thus require one or more protection layer(s).

The flexibility of a PV segment or PV unit, or the capability for such PV unit or PV segment to take a curved form or a non-planar form or an angular form (or a combination of such forms), may depend on: (i) the flexibility of the particular PV cells from which the entire PV module is composed, and (ii) the composition and/or selection and/or structure of coating layers, encapsulating layers, protective layers, electricity conductive layers (or components), and/or or other functional layers that are utilized in forming the PV unit.

Some PV units are based upon rigid silicon wafers, which are very brittle and which have a very low level of flexibility; which are mounted on rigid structures that are protected by at least a glass layer as a top protective layer. Some semi-flexible PV units may be based upon one or more types of PV cells that are protected by a polymer-based top-sheet or top-side sheet, and may have a semi-flexible stack of materials or layers which limit the extent to which the PV unit can be bent (or rolled, or folded, or curved, or bent, or bended), mainly in order to protect the underlying PV cells (which are brittle) from breakage. Some fully-flexible PV modules may be based upon one or more relevant technologies, and may include PV cells that are “sandwiched” between polymeric layers on both sides.

The Applicants have realized that conventional PV devices include, exclusively, a single type of PV cells or a single type of PV segments: for example, a first conventional PV device includes, exclusively, only rigid and non-flexible and planar PV segments, forming together an entire conventional PV device that is rigid and planar in its entirety; or, a second conventional PV device includes, exclusively, only flexible and non-planar PV segments, forming together an entire conventional PV device that is flexible and is curved (and/or angular) and non-planar.

The Applicants have realized that there does not exist, and that there is a need for, a combined or hybrid PV device. Accordingly, some embodiments provide a combined or hybrid PV device, which includes, within one encapsulant, or within one set of the same encapsulants, both a rigid PV segment and a flexible PV segment. Additionally or alternatively, some embodiments provide a combined or hybrid PV device that includes, within one encapsulant, or within one set of the same encapsulants, both a rigid and planar PV segment and a flexible and non-planar PV segment.

The Applicants have realized that the mechanical and/or electrical components (or characteristics) of a rigid and/or planar PV segment or PV unit, may be different from the mechanical and/or electrical components (or characteristics) of a flexible and/or non-planar PV segment or PV unit. The Applicants have realized that it may be beneficial to overcome such possible “mismatch” in the components or characteristics of PV units, in order to enable the production of a single PV device that includes therein both a rigid PV unit and a flexible PV unit, that are interconnected mechanically and/or electrically, and that are all encapsulated within the same encapsulant and/or within the same set of protective layers or protective encapsulants.

The Applicants have realized that conventional PV units have utilized only a single uniform type of PV cells (e.g., either rigid or flexible, but not both); in order to avoid a mismatch in their electrical characteristics (e.g., current and voltage) along the surface of the PV unit; and/or in order to simplify the production of the conventional PV unit via simple matching of current and/or voltage in serial or parallel interconnections. However, this assumes that the entire surface of the PV unit is experiencing the same illumination conditions (e.g., no shades; no reflections; no different lighting angles across the surface of the PV unit), and the Applicants have realized that this assumption may not necessarily hold true, and thus it may be beneficial to make the additional efforts to combine and connect together PV segments of different types (e.g., a rigid planar PV segment, with a flexible curved PV segment, or with a flexible angular PV segment); thereby producing a combined or hybrid PV device which may be installed or mounted or placed or positioned at particular locations or places (e.g., a roof of a house; a horizontal wall; a vertical wall; a slanted wall; a vehicle; a marine vessel; an aircraft; or the like), to accommodate such non-uniform lighting conditions that may exist, and/or to accommodate non-planar locations or items on which the PV device is mounted.

The Applicants have also realized that the electrical characteristics may differ between different types of PV cells, as well as in different lighting conditions; however, the voltage of the electricity that is generated is mainly determined by the type of material from which the PV cell is formed, whereas the electric current is more significantly affected by the actual lighting conditions.

The Applicants have realized that rigid PV segments have been used only in rigid and planar PV units or PV devices; and that flexible PV segments have been used only in flexible and non-planar PV units or PV devices.

The Applicants have also realized that the flexiangbility of flexible PV cells or flexible PV segments, enables to utilize them in the manufacturing of not only a fully-flexibly PV device, but also in the manufacturing of a semi-flexible PV device, and/or in the manufacturing of a PV device that is not necessarily flexible and/or that is not necessarily subject to mechanical forces or bending or rolling or curving or folding; and/or in the manufacturing of a PV device having a non-planar or non-flat structure, or having a curvature, or having one or more curved regions and/or concave regions and/or convex regions and/or angular regions; and flexible PV segments may be used for manufacturing such PV devices, having such non-planar or non-flat structure, instead of using one or more rigid planar PV cells that may fracture and/or break. The Applicants have also realized that the same is also true with regard to PV devices or PV articles which have joints of areas or joints of regions that need to be functionally flexible, but also have other surface areas that remain or stay rigid and are not expected to become curved or angular or non-planar, and/or that are not expected to be subject to folding forces and/or bending forces and/or rolling forces and/or curving forces, and/or are expected to maintain no curvature or a low degree or low level of spatial curvature. The Applicants have realized that the greater the curvature of the PV article, the greater is the degree of flexibility or the level of flexibility of the PV cells that is needed in order to withstand the incorporation of such PV cells into the curved (or angular) non-planar PV article. Therefore, realized the Applicants, flexible PV cells may be suitable for manufacturing PV modules having large curvature or having sharp angles, and rigid PV cells may be less suitable for those purposes.

The Applicants have realized that flexible PV cells often exhibit lower efficiency (in electricity generation) relative to that of rigid PV cells; and that curved PV articles or curved PV devices often encounter different lighting conditions at different areas or regions thereof; and that flexible PV devices may exhibit a smaller time-period of efficient performance relative to rigid planar (or flat) PV devices.

Some embodiments may combine PV cells or PV segments of different types (e.g., a PV segment that is rigid and planar; a PV segment that is rigid and non-planar; a PV segment that is flexible and curved; a PV segment that is flexible and planar), to form a single, unified, electronic surface PV product or PV device or PV article, which is not flat in its entirety, or which is not entirely flat, or which is not entirely planar.

In some embodiments, the combined or hybrid PV device may include multiple PV cells or multiple PV segments, each one of them having a different degree or a different level of flexibility or elasticity or rigidity or rigidness, and all those different PV segments are combined and connected (e.g., mechanically and/or electrically) within the same single PV device, and are all coated by, or encapsulated within, or “sandwiched” by, the same protective layer(s) and/or the same set of multiple protective layers.

Some embodiments may utilize, at a particular location or region of the PV device or the PV article, the particular type of PV cell or PV segment having the highest electricity-generating efficiency (and/or the highest cost-effective level of such efficiency), that can still withstand the curvature requirements (e.g., due to a planned installation or an expected mounting of that region of the PV device, onto or adjacent to a curved location or a non-planar location or object), and that can still withstand the mechanical stress that is expected to occur at such location (e.g., during production, and/or during mounting or installation, and/or during the service life of the PV device).

Some embodiments may thus enable incorporation of several different types of PV cells or PV segments, in the same single unified PV article or PV device. For example, rigid (and planar) PV cells or PV segments, having high electricity-generating efficiency, would be used at flat regions or flat portions or flat locations of the PV article (e.g., locations or regions that are not expected or intended to undergo bending or folding or rolling or curving); whereas, flexible PV cells or flexible PV segments would be used at other locations or regions or areas of the same PV device which require or which have a spatial curvature (e.g., which would cause rigid PV cells to fracture or to break) or which require some degree of mechanical flexibility in those particular regions of portions of the unified PV device.

The PV device is thus divided into areas or locations or regions or portions, each one of them having different electrical and/or mechanical characteristics, taking into account the type of PV cells that can match the intended usage of that particular device-portion or device-region, and/or taking into account the expected lighting conditions that are expected or are estimated with regard to each particular device-portion or device-region.

In such combined or hybrid PV device, for example, a group of PV cells that are expected to produce the same or similar electric currents may be connected to each other in series; whereas, a group of PV cells that are expected to produce the same or similar electric voltages may be connected to each other in parallel.

In some embodiments, “similar” currents or “similar” voltages may be defined or pre-defined, for example, by using numerical threshold value(s) of similarity; for example, value A may be defined as “similar” to value B, if (for example) 0.9A<B<1.1A, or if value A is within 10 percent (or, within N percent, where N is a pre-defined number) more than value B or less than value B. Other suitable ways may be used to define a level of similarity between values, currents, voltages, illumination conditions, efficiency, or other characteristics or parameters.

Accordingly, in some embodiments, the difference in voltage and/or current between a first PV cell or a first PV segment, and a second PV cell or a second PV segment, may be overcome or mitigated or alleviated, by selecting in advance an electrical connection in parallel or in series. In other embodiments, a mismatch in current and/or voltage may not necessarily be overcome only by selective grouping of PV cells (or PV segments) in parallel or in series, and local Direct Current to Direct Current (DC/DC) converter(s) may be utilized within the combined or hybrid PV device, optionally with maximum power point tracking capabilities, such converters being connected to each group of PV cells in order to enable matching of current and/or voltage, and/or in order to increase the overall production of electricity at the expense of a more complicated or expensive solution or structure.

Some embodiments may be particularly suitable or particularly efficient for utilization in a situation where a PV device or a PV article is needed for being mounted on, or placed at or near, a curved object or curves surface, or a non-planar object or non-planar surface, or a mixed-shape or mixed-curvature object; for example, a curved object, a non-planar object, a vehicle, a car, a marine vessel, an aircraft, a drone, an object having patterned surface(s) and/or curved surface(s), car roof, car hood, car bonnet, carbon fiber and/or glass fiber articles, metal objects, metal car roof, carbon or glass fiber roof (or bonnet or hood or other vehicular part), plastic elements, spoilers, aerodynamic add-ons or extensions, a truck, a bus, a Recreational Vehicle (RV), a ship, a boat, a yacht, and/or other vessels; as well as stationary and/or non-mobile objects, for example, a non-planar roof of a house or a business venue, a non-planar storage facility or storage container, or the like.

In some embodiments, the rigid and/or planar PV segments or PV units, that are utilized in the combined or hybrid PV device, may be formed of crystalline silicon.

In some embodiments, the flexible and/or curved and/or angular and/or non-planar PV segments or PV units, that are utilized in the combined or hybrid PV device, may include one or more PV units that are described in patent publication number US 2020/0212238 A1 and/or in patent publication number WO 2020/136653 A1, both of which are hereby incorporated by reference in their entirety; for example, being a PV unit that is structured, using protrusions or channels or craters that are introduced into the wafer or the substrate, to become shock absorbent and/or more resilient to mechanical forces.

In some embodiments, the combined or hybrid PV article comprises one or more composite material(s), which may include, for example, glass and/or carbon fiber and/or other composite materials. Optionally, flexible and/or stretchable and/or elastic polymer(s) may be included in the composite material(s), to provide elasticity and/or flexibility and/or stretching ability to the combined or hybrid PV article or to selected regions thereof. Such polymer(s) may include, for example, polyester, epoxy, polyolefin, and/or a combination of two or more of these materials and/or other materials.

In some embodiments, a flexible PV segment of the combined or hybrid PV article may comprise PV cells formed of, for example: CuIn(x)Ga(x−1)Se(y)S(y−1), wherein “x” is 0 or 1, wherein “y” is 0 or 1; amorphous silicon; organic solar cells, organic PV cells; perovskite solar cells, perovskite PV cells; Cs2SnI6 solar cells or PV cells; CdTe solar cells or PV cells; Se solar cells or PV cells; GaAs solar cells or PV cells; InP solar cells or PV cells; solar cells and/or PV cells that are formed of solar-paint material(s) (e.g., as described in patent publication number US 2016/0308155 A1, which is hereby incorporated by reference in its entirety); and/or a combination of two or more of the above.

In some embodiments, the rigid and/or planar PV segments of the combined or hybrid PV device may include, for example: mono-crystalline PV cells; poly-crystalline silicon PV cells; PV cells that include or that are formed of CdTe, InP, GaAs, CIGS, Perovskite, and/or the above-mentioned solar-paint material; and/or a combination of two or more of the above.

In some embodiments, a rigid and/or planar PV cell, and a neighboring or adjacent or inter-connected flexible or semi-flexible PV cell, are both coated with, or are mounted beneath, or are adjacent to, a single unified glass layer, or a set of several glass layers; or, they are sandwiched or embedded within two glass layers, or between two sets of multiple glass layers; and such glass layer(s) may provide mechanical protection to at least some regions of the PV device, while also being transparent to sunlight or light.

In some embodiments, a rigid and/or planar PV cell, and a neighboring or adjacent or inter-connected flexible or semi-flexible PV cell, are both coated with, or are mounted beneath, or are adjacent to, a single unified polycarbonate layer, or a set of several polycarbonate layers; or, they are sandwiched or embedded within two polycarbonate layers, or between two sets of multiple polycarbonate layers; and such polycarbonate layer(s) may provide mechanical protection to at least some regions of the PV device, while also being transparent to sunlight or light.

In some embodiments, optionally, a metal layer or a metallic support layer, or several such layers, may be mounted or connected or placed beneath the rigid PV cell(s) and beneath the nearby flexible PV cell(s); and such metal layer(s) may provide mechanical support to the structure of the PV device; and they need not be transparent to light as they are located beneath the PV cells, or on the side of the PV cell that is not intended to collect light. In some embodiments, such support layer is a unified support layer, that runs beneath or runs under all of the different types of PV cells or PV segments of that PV device; for example, a single unified support layer (e.g., metallic) which runs beneath, and supports, both the rigid PV segments and the co-located flexible PV segments. In some embodiments, such metal layer(s) or support layer(s) are insulated from any conducting poles, so as not to present an electrical hazard and to avoid a short to the electric circuit; and/or, in some embodiments, such metal layer(s) may be formed or structured in a non-planar form, to follow or to trace the spatial structure of the PV segments that are supported, and particularly to follow and to support and to trace beneath any curved or angular or non-planar PV segments; and/or, in some embodiments, such metallic support layer(s) may support only a portion of each PV segment (e.g., supporting only 70% or only 80% or only 90% of the bottom-side area of each PV segment), and not necessarily the entire 100% of the bottom-side area of each PV segment; for example, in order to allow placement of conducting electrodes at edges or sides of each PV segment without such electrodes touching the metallic support layer.

In some embodiments, the combined or hybrid PV device is manufactured using one or more of the following methods: autoclave, hot press, Pressure Sensitive Adhesive (PSA), epoxy, Resin Transfer Molding (RTM), Vacuum Assisted Resin Infusion (VARI), humidity curing, Ultra Violet (UV) curing, a process utilizing one or more adhesives, a coating process, or the like.

In some embodiments, the solar cells or the PV cells of the combined or hybrid PC device, or the various PV segments of the combined or hybrid PV device, are encapsulated within a layer of composite material(s), or within a set of two or more layers of composite material(s). For example, one or more protective layer(s) that are located above the PV cells (e.g., located at the “sunny side”, the side that is intended to face the illumination source) are transparent, and may be composed of materials such as, for example, a pre-preg epoxy layer (e.g., a layer of epoxy or resin that is pre-impregnated with fibers), a wet lay-up layer (e.g., of epoxy or resin that is enriched with fiber), a layer of glass fiber(s) or a glass mat, or the like. In some embodiments, one or more layers or protective layers may cover or coat or protect the PV cells from beneath, located at the “non-sunny side” (e.g., the side that is opposite to said “sunny side”); and such bottom-side protective layer(s) may be formed of the same material(s) that are used for the top-side protective layer(s), and/or from other suitable materials as the bottom-side protective layers need not necessarily be transparent to light; for example, layers containing carbon, flax, or other natural or man-made fibers or synthetic fibers. In some embodiments, the combined or hybrid PV article produced may have a lower level of mechanical flexibility, and may be characterized by having multiple areas or regions of different spatial curvature that are produced simultaneously.

In some embodiments, the PV segments (one or more rigid PV segments and nearby, co-located, one or more flexible PV segments) are encapsulated or sandwiched or embedded within one or more protective layers of thermoplastic material(s). For example, protective layer(s) that are located above the PV cells (e.g., at the “sunny side” which is intended to face the sun or the illumination source) are transparent, and may be composed of one or more materials such as, for example, polycarbonate, polymethyl methacrylate, or other transparent materials, or a combination or mixture of two or more such materials. The layer(s) that are located below or beneath or under the PV cells (e.g., not facing the sun, or not facing the illumination source) may optionally be transparent (e.g., to thereby provide a PV device that is bi-facial, and/or that is capable of collecting light from two opposite directions or from to different directions and converting such incoming light to electricity), or may be non-transparent; and may be formed of one or more materials such as, for example, polycarbonate, polymethyl methacrylate, polyurethane, polyethylene, polypropylene, polyamide, Acrylonitrile Butadiene Styrene (ABS), rubber, plastic, polymer, flexible plastic, flexible polymer, rigid plastic, rigid polymer, or other polymeric materials, or a combination or mixture of two or more of such materials.

In some embodiments, the PV device may optionally include a pre-preg or wet lay-up of epoxy and/or resin, and/or glass fibers and/or a glass mat, and/or fibers of a mat, of other materials such as, for example, carbon, flax, or other natural or man-made or artificial or synthetic fibers. In such embodiments, the PV device that is produced, or the relevant PV segments that include such material(s), may have a lower level of flexibility, and may be characterized by having regions or areas or PV segments of different curvature that are produced or manufactured simultaneously or concurrently or within a single unified manufacturing process.

In some embodiments, the PC segments may be encapsulated or pre-encapsulated or coated with, or sandwiched within, one or more soft material(s) such as, for example, Polyolefin Elastomer (POE), Thermoplastic Polyurethane (TPU), Thermoplastic Olefin or Thermoplastic Polyolefin (TPO) or olefinic thermoplastic elastomer, Ethylene-vinyl acetate (EVA), poly (ethylene-vinyl acetate) (PEVA), and/or similar encapsulants. In some embodiments, all, or most, or at least some of the encapsulated or pre-encapsulated PV cells or PV segments (e.g., rigid and/or flexible PV segments), or at least some region of the PV cell matrix, is then further encapsulated or re-encapsulated within a rigid thermosetting or thermoplastic system, as described above. Other parts are re-encapsulated in a flexible thermoplastic system thus creating a flexible area of the article.

Some embodiments may comprise a hybrid PV device or a hybrid PV article; for example, a non flat-surface based PV electronic article, containing therein PV electronic units having different levels of curvature or having different spatial curvature properties or having different curvature characteristics. Some embodiments may comprise a flexible-surface based PV electronic article, wherein different PV units or PV segments that form the PV article exhibit different levels of mechanical flexibility and/or bending ability and/or folding ability and/or rolling ability and/or elasticity and/or stretch-ability.

In some embodiments, the flexibility of the PV electronic units enables the creation of the non-flat surface during manufacturing process. In some embodiments, the different flexibility of the PV units in different areas of the PV article enable flexing or bending or folding or rolling of the article during its operation, at different ratios, and at different areas or regions or portions of the PV article.

In some embodiments, the PV article is a solar module, or a PV device able to convert light or light energy into electricity or electric energy or electric voltage or electric current.

In some embodiments, the PV article is, or comprises, or is mounted on, or is configured to be mounted on, or is configured to be part of, a vehicular body-part; and particularly, the non-flat surface of the PV article is an automotive body-part or a vehicular body-part, or is mountable on a vehicular body-part.

In some embodiments, at least some of the electronic components of the PV article are solar cells or PV cells having different levels of mechanical flexibility. In some embodiments, flexible PV cells or flexible solar cell include, for example, toughened silicon solar cells or toughened substrate solar cells or shock-resistant solar cells or force-resilient solar cells, or PV cells that are manufactured by introducing craters or channels or gaps into a silicon or into a substrate or into a wafer of a PV unit, to provide resilience to mechanical forces and/or to provide shock absorption capabilities and/or to provide shock propagation capabilities and/or to provide enhanced resistance to withstand mechanical forces.

In some embodiments, one or more of the rigid PV cells or the rigid PV segments include, for example, mono-crystalline and/or poly-crystalline silicon solar cells or PV cells.

In some embodiments, the solar cells or the PV cells, or groups of solar cells or groups of PV cells, are connected in series in areas that are expected or intended to receive approximately the same amount and/or properties of incoming radiation and/or incoming illumination, and/or that have or that generate approximately the same expected electric current.

In some embodiments, the solar cells or the PV cells, or groups of solar cells or groups of PV cells, are connected in parallel in areas that are expected or intended to receive different amount and/or different properties of incoming radiation and/or incoming illumination, and/or that have or that generate different levels of electric current.

In some embodiments, the manufacturing process of the hybrid PV device may include one or more of, or may utilize one or more of: autoclave; hot press; lamination to metal, aluminum, glass, fiberglass, carbon fiber, fiber composites, particulate composites, paint, polymers, using PSA, magnet(s), magnetic layer(s), magnetic components, mechanical attachment, thermal adhesive, UV curable adhesive, immersion, and/or other production processes and/or production materials.

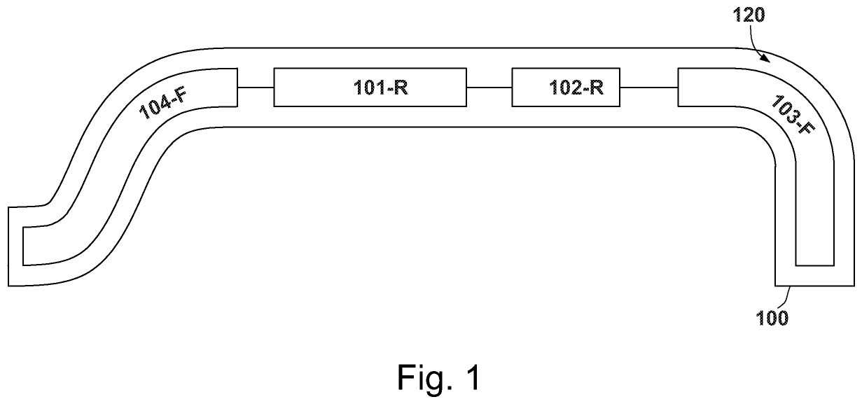

Reference is made to FIG. 1, which is a schematic illustration of a hybrid PV device 100, in accordance with some demonstrative embodiments. PV device 100 comprises for example, two rigid and planar PV segments (101-R and 102-R), and two flexible PV segments (103-F and 104-F) which are shown at a curved or non-planar position but may be folded or bent or rolled or otherwise shape-shifted to acquire other shape(s). The four PV segments are interconnected mechanically and/or electrically; and they are all encapsulated within a single unified sealant 120 (or, within a single unified group of multiple sealants or of multiple protective layers). The various PV segments need not be identical to each other; and they may have different shapes, different thickness values, different dimensions, different length values, different width values, different levels of efficiency in generating electricity from light or in converting light into electricity, and/or other properties which may have different values.

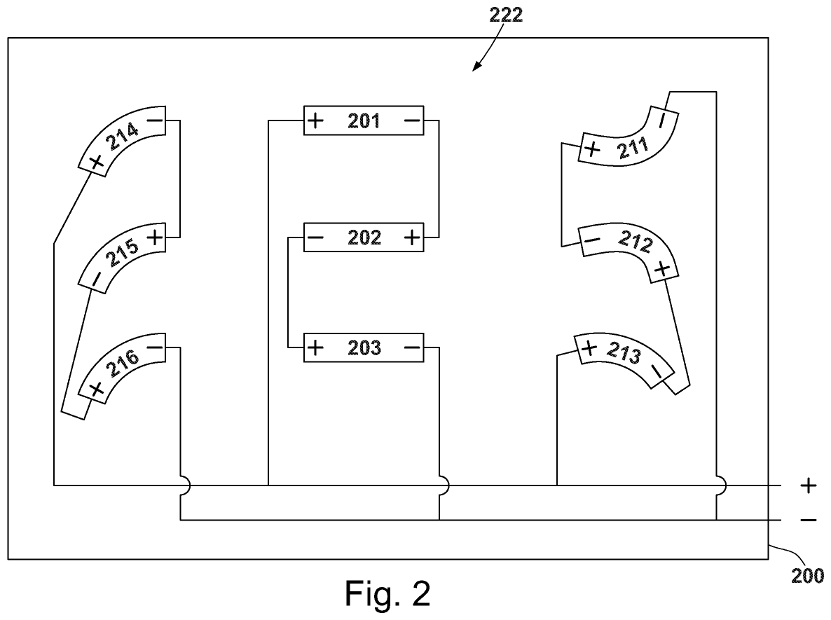

Reference is made to FIG. 2, which is a schematic illustration of a hybrid PV device 200, in accordance with some demonstrative embodiments. PV device 200 comprises for example, three rigid PV segments 201-203, and six flexible PV segments 211-216; all of them being electrically and/or mechanically inter-connected; and all of them being encapsulated within a single unified sealant 120 (or, within a single unified group of multiple sealants or of multiple protective layers).

For demonstrative purposes, some portions of the discussion herein may relate to “silicon” as a possible semiconductor or substrate or material from which the PV segment(s) or the PV cell(s) may be formed; however, this is only a non-limiting example, and some embodiments may include or may utilize, or may be formed of, other suitable substrate(s) and/or material(s) and/or semiconductor(s), instead of silicon and/or in addition to silicon.

In some embodiments, a hybrid photovoltaic (PV) device comprises: (a) a rigid PV segment, comprising a first set of one or more PV cells that convert incoming light to electricity, wherein the rigid PV segment is non-foldable and non-bendable; (b) a co-located flexible PV segment, comprising a second set of one or more PV cells that convert incoming light to electricity, wherein the flexible PV segment is foldable or bendable, wherein folding or bending of the flexible PV segment does not damage at all (or, does not significantly damage, or, essentially does not damage) the flexible PV segment (and/or its operational functionality, and/or its operational properties, and/or its operational efficiency in converting light into electricity); (c) one or more electric connectors, that connect between (i) electric current or electric voltage that are generated by the rigid PV segment, and (ii) electric current or electric voltage that are generated by the flexible PV segment; (d) a unified encapsulation layer, which encapsulates together both the rigid PV segment and the co-located flexible PV segment. The rigid PV segment, the co-located flexible PV segment, the one or more electric connectors, and the unified encapsulation layer, form together said hybrid PV device which is a single stand-alone PV device that converts incoming light to electricity and that has at least one rigid region corresponding to said rigid PV segment and at least one flexible region corresponding to said co-located flexible PV segment.

In some embodiments, the rigid PV segment is a rigid planar PV segment; the flexible PV segment is a flexible non-planar (e.g., curved and/or angular) PV segment; the rigid planar PV segment and the flexible non-planar PV segment are co-located next to each other and are electrically connected to each other, and are encapsulated by the same unified encapsulation layer.

In some embodiments, the rigid PV segment is a rigid planar PV segment; the flexible PV segment is a flexible planar PV segment; the rigid planar PV segment and the flexible planar PV segment are co-located next to each other and are electrically connected to each other, and are encapsulated by the same unified encapsulation layer.

In some embodiments, the rigid PV segment is a rigid non-planar (e.g., curved and/or angular) PV segment; the flexible PV segment is a flexible non-planar (e.g., curved and/or angular) PV segment; the rigid non-planar PV segment and the flexible non-planar PV segment are co-located next to each other and are electrically connected to each other, and are encapsulated by the same unified encapsulation layer.

In some embodiments, the rigid PV segment is a rigid non-planar (e.g., curved and/or angular) PV segment; the flexible PV segment is a flexible planar PV segment; the rigid non-planar PV segment and the flexible planar PV segment are co-located next to each other and are electrically connected to each other, and are encapsulated by the same unified encapsulation layer.

In some embodiments, the rigid PV segment is a pre-encapsulated rigid PV segment, that is pre-encapsulated by itself within a first particular encapsulant which is functionally suitable for rigid PV segments; the rigid PV segment is a pre-encapsulated rigid PV segment, that is pre-encapsulated by itself within a second particular encapsulant which is functionally suitable for flexible PV segments and which is different from the first particular encapsulant of the rigid PV segment; the pre-encapsulated rigid PV segment and the co-located pre-encapsulated flexible PV segment are both further encapsulated by said unified encapsulation layer of the PV hybrid device.

In some embodiments, said hybrid PV device comprises said rigid PV segment at a first particular device-region that is intended to be maintained non-folded and not-bended; and said hybrid PV device comprises said flexible PV segment at a second particular device-region that is intended to be folded or bended.

In some embodiments, the rigid PV segment is configured to generate, on average, a first value I1 of electric current; the flexible PV segment is configured to generate, on average, a second value I2 of electric current; a difference between I1 and I2 is less than 10 percent (or, less than 5% or 15% or 20% or 25%) of I1; wherein the rigid PV segment and the flexible PV segment are electrically connected to each other in series due to said difference between I1 and I2 (or, due to the ratio between said different and I1; or, due to the ration between said difference and I2).

In some embodiments, the rigid PV segment is configured to generate, on average, a first value I1 of electric current; the flexible PV segment is configured to generate, on average, a second value I2 of electric current; a difference between I1 and I2 is at least 10 percent (or, is at least 5% or 15% or 20% or 25%) of I1; the rigid PV segment and the flexible PV segment are electrically connected to each other in parallel due to said difference between I1 and I2 (or, due to the ratio between said different and I1; or, due to the ration between said difference and I2).

In some embodiments, the hybrid PV device comprises a plurality of co-located PV segments which comprise: a plurality of rigid PV segments and a plurality of flexible PV segments, that are all co-located; each one of the rigid PV segments is electrically connected, directly or indirectly, to at least one of the flexible PV segments; each one of the flexible PV segments is electrically connected, directly or indirectly, to at least one of the rigid PV segments.

In some embodiments, said hybrid PV device comprises a first particular rigid PV segment that is co-located adjacent to a first particular flexible PV segment; the first particular rigid PV segment is configured to generate, on average, a first value I1 of electric current; the first particular flexible PV segment is configured to generate, on average, a second value I2 of electric current; wherein a difference between I1 and I2 is less than 10 percent of I1; the first particular rigid PV segment and the first particular flexible PV segment are electrically connected to each other in series due to said difference between I1 and I2; said hybrid PV device comprises a second particular rigid PV segment that is co-located adjacent to a second particular flexible PV segment; the second particular rigid PV segment is configured to generate, on average, a third value I3 of electric current; the second particular flexible PV segment is configured to generate, on average, a fourth value I4 of electric current; a difference between I3 and I4 is less than 10 percent of I3; the second particular rigid PV segment and the second particular flexible PV segment are electrically connected to each other in series due to said difference between I3 and I4.

In some embodiments, the hybrid PV device comprises a plurality of co-located PV segments which comprise: a plurality of rigid PV segments and a plurality of flexible PV segments, that are all co-located; a pair of two co-located PV segments, that generate respectively a first value of average electric current I1 and a second value of average electric current I2, are electrically connected to each other in series if a difference between I1 and I2 is less than N percent of I1, and are electrically connected to each other in parallel if the difference between I1 and I2 is at least N percent of I1; wherein N is a pre-defined threshold value between 0 and 25.

In some embodiments, at least one of the PV segments comprises: a silicon wafer, having a plurality of craters that penetrate into the silicon wafer and do not reach a bottom side of the silicon wafer; wherein the plurality of craters assist in mechanical forces absorption and provide resilience to mechanical forces.

In some embodiments, the rigid PV segment is configured to generate, on average, a first value I1 of electric current; the co-located flexible PV segment is configured to generate, on average, a second value I2 of electric current; a difference between I1 and I2 is at least 10 percent of I1; the rigid PV segment and the co-located flexible PV segment are electrically connected to each other indirectly via a Direct Current to Direct Current (DC/DC) converter unit that converts a level of electric current generated by the rigid PV segment to a level of electric current generated by the flexible PV segment.

In some embodiments, the rigid PV segment is configured to generate, on average, a first value I1 of electric current; the co-located flexible PV segment is configured to generate, on average, a second value I2 of electric current; a difference between I1 and I2 is at least 10 percent of I1; the rigid PV segment and the co-located flexible PV segment are electrically connected to each other indirectly via a Direct Current to Direct Current (DC/DC) converter unit that converts a level of electric current generated by the flexible PV segment to a level of electric current generated by the rigid PV segment.

In some embodiments, the unified encapsulation layer, which encapsulates together both the rigid PV segment and the co-located flexible PV segment, comprises at least: (A) a top-side encapsulating layer, which is transparent and enables passage of light therethrough, and is located at a first side of the PV device that is intended to receive incoming illumination for electricity generation; and (B) a bottom-side encapsulating layer, which is non-transparent and blocks passage of light therethrough, and is located at a second side of the PV device that is not intended to receive incoming illumination for electricity generation.

In some embodiments, the unified encapsulation layer, which encapsulates together both the rigid PV segment and the co-located flexible PV segment, comprises at least: (A) a top-side encapsulating layer, which is transparent and enables passage of light therethrough, and is located at a first side of the PV device that is intended to receive incoming illumination for electricity generation; and (B) a bottom-side encapsulating layer, which is transparent and enables passage of light therethrough, and is located at a second side of the PV device that is also intended to receive incoming illumination for electricity generation; the hybrid PV device is a bi-facial PV device or a dual-direction PV device that is capable of receiving incoming light at two opposite sides of the hybrid PV device and converts said incoming light to electricity.

In some embodiments, the bottom-side encapsulating layer comprises a metal layer that provides structural and mechanical support to said hybrid PV device; said metal layer is located within said unified encapsulation layer, which encapsulates together both the rigid PV segment and the co-located flexible PV segment.

In some embodiments, the rigid PV segment is located at a first particular region of the hybrid PV device that is expected to receive a first level of light energy; the flexible PV segment is located at a second particular region of the hybrid PV device that is expected to receive a second level of light energy that is smaller than said first level of light energy.

In some embodiments, the unified encapsulation layer, which encapsulates together both the rigid PV segment and the co-located flexible PV segment, comprises: (A) a first encapsulation layer, which is a transparent top-side unified encapsulation layer that covers a top-side of the rigid PV segment and a top-side of the flexible PV segment; and (B) a second encapsulation layer, which is a non-transparent bottom-side unified encapsulation layer that covers a bottom-side of the rigid PV segment and a bottom-side of the flexible PV segment.

In some embodiments, the unified encapsulation layer, which encapsulates together both the rigid PV segment and the co-located flexible PV segment, comprises: (A) a first encapsulation layer, which is a transparent top-side unified encapsulation layer that covers a top-side of the rigid PV segment and a top-side of the flexible PV segment; and (B) a second encapsulation layer, which is a transparent bottom-side unified encapsulation layer that covers a bottom-side of the rigid PV segment and a bottom-side of the flexible PV segment; wherein the hybrid PV device is a bi-facial PV device or a dual-direction PV device, that is capable of receiving incoming light at two opposite sides of the hybrid PV device and converts said incoming light to electricity.

In some embodiments, the top-side unified encapsulation layer is formed of one or more materials selected from: polycarbonate, polymethyl methacrylate; wherein the bottom-side unified encapsulation layer is formed of one or more materials selected from: polycarbonate, polymethyl methacrylate, polyurethane, polyethylene, polypropylene, polyamide, Acrylonitrile Butadiene Styrene (ABS), rubber, plastic, polymer, flexible plastic, flexible polymer, rigid plastic, rigid polymer.

In some embodiments, the rigid PV segment is pre-encapsulated within a first pre-encapsulation material, separately from the co-located flexible PV segment; the flexible PV segment is pre-encapsulated within a second pre-encapsulation material, separately from the co-located rigid PV segment; wherein the first pre-encapsulation material is a material selected from: Polyolefin Elastomer (POE), Thermoplastic Polyurethane (TPU), Thermoplastic Olefin or Thermoplastic Polyolefin (TPO) or olefinic thermoplastic elastomer, Ethylene-vinyl acetate (EVA), poly (ethylene-vinyl acetate) (PEVA); wherein the second pre-encapsulation material is a material selected from: Polyolefin Elastomer (POE), Thermoplastic Polyurethane (TPU), Thermoplastic Olefin or Thermoplastic Polyolefin (TPO) or olefinic thermoplastic elastomer, Ethylene-vinyl acetate (EVA), poly (ethylene-vinyl acetate) (PEVA).

In some embodiments, the hybrid PV device comprises a plurality of co-located PV segments which include at least one rigid PV segment and at least one flexible PV segment; wherein at least a first PV segment of said plurality of co-located PV segments is electrically connected in series to a second PV segment of said plurality of PV segments; wherein at least a third PV segment of said plurality of co-located PV segments is electrically connected in parallel to a fourth PV segment of said plurality of PV segments.

In some embodiments, the hybrid PV device comprises a plurality of co-located PV segments which include at least one rigid PV segment and at least one flexible PV segment; at least a first rigid PV segment of said plurality of co-located PV segments is electrically connected in series to a second flexible PV segment of said plurality of PV segments; at least a third rigid PV segment of said plurality of co-located PV segments is electrically connected in parallel to a fourth flexible PV segment of said plurality of PV segments.

For demonstrative purposes, some portions of the discussion may relate to a particular numerical value (e.g., “10 percent”); however, this is only a non-limiting example, and such particular numerical value may be replaced with another particular numerical value (e.g., “N”) that is pre-defined and/or hard-coded and/or modifiable (depending on the particular implementation), and/or that is configured to accommodate a particular spatial structure and/or a particular operational functionality.

In some embodiments a “PV segment” may include a single, discrete, photovoltaic cell. In other embodiments, a “PV segment” may include, or may be formed of, a set or group or collection of multiple photovoltaic cells (or micro PV cells, or nano PV cells) which may be electrically and/or mechanically inter-connected.

In some embodiments, the hybrid PV device is a vehicular component that generates electricity for a vehicle. In some embodiments, the hybrid PV device is a marine vessel component that generates electricity for a marine vessel. In some embodiments, the hybrid PV device is an aircraft component that generates electricity for an aircraft. In some embodiments, the hybrid PV device is a rooftop PV solar panel that generates electricity for a venue or a home or an office or a non-mobile structure or a mobile structure.

Functions, operations, components and/or features described herein with reference to one or more embodiments of the present invention, may be combined with, or may be utilized in combination with, one or more other functions, operations, components and/or features described herein with reference to one or more other embodiments of the present invention. The present invention may comprise any possible combinations, re-arrangements, assembly, re-assembly, or other utilization of some or all of the modules or functions or components that are described herein, even if they are discussed in different locations or different chapters of the above discussion, or even if they are shown across different drawings or multiple drawings.

While certain features of some demonstrative embodiments of the present invention have been illustrated and described herein, various modifications, substitutions, changes, and equivalents may occur to those skilled in the art. Accordingly, the claims are intended to cover all such modifications, substitutions, changes, and equivalents.

1. A hybrid photovoltaic (PV) device, comprising:
a rigid PV segment, comprising a first set of one or more PV cells that convert incoming light to electricity, wherein the rigid PV segment is non-foldable and non-bendable;
a co-located flexible PV segment, comprising a second set of one or more PV cells that convert incoming light to electricity, wherein the flexible PV segment is foldable or bendable, wherein folding or bending of the flexible PV segment does not significantly damage the flexible PV segment;
one or more electric connectors, that connect between (i) electric current or electric voltage that are generated by the rigid PV segment, and (ii) electric current or electric voltage that are generated by the flexible PV segment;
a unified encapsulation layer, which encapsulates together both the rigid PV segment and the co-located flexible PV segment;
wherein the rigid PV segment, the co-located flexible PV segment, the one or more electric connectors, and the unified encapsulation layer, form together said hybrid PV device which is a single stand-alone PV device that converts incoming light to electricity and that has at least one rigid region corresponding to said rigid PV segment and at least one flexible region corresponding to said co-located flexible PV segment.

2. The hybrid PV device of claim 1,
wherein the rigid PV segment is a rigid planar PV segment,
wherein the flexible PV segment is a flexible non-planar PV segment,
wherein the rigid planar PV segment and the flexible non-planar PV segment are co-located next to each other and are electrically connected to each other, and are encapsulated by the same unified encapsulation layer.

3. The hybrid PV device of claim 1,
wherein the rigid PV segment is a rigid planar PV segment,
wherein the flexible PV segment is a flexible planar PV segment,
wherein the rigid planar PV segment and the flexible planar PV segment are co-located next to each other and are electrically connected to each other, and are encapsulated by the same unified encapsulation layer.

4. The hybrid PV device of claim 1,
wherein the rigid PV segment is a rigid non-planar PV segment,
wherein the flexible PV segment is a flexible non-planar PV segment,
wherein the rigid non-planar PV segment and the flexible non-planar PV segment are co-located next to each other and are electrically connected to each other, and are encapsulated by the same unified encapsulation layer.

5. The hybrid PV device of claim 1,
wherein the rigid PV segment is a rigid non-planar PV segment,
wherein the flexible PV segment is a flexible planar PV segment,
wherein the rigid non-planar PV segment and the flexible planar PV segment are co-located next to each other and are electrically connected to each other, and are encapsulated by the same unified encapsulation layer.

6. The hybrid PV device of claim 1,
wherein the rigid PV segment is a pre-encapsulated rigid PV segment, that is pre-encapsulated by itself within a first particular encapsulant which is functionally suitable for rigid PV segments;
wherein the rigid PV segment is a pre-encapsulated rigid PV segment, that is pre-encapsulated by itself within a second particular encapsulant which is functionally suitable for flexible PV segments and which is different from the first particular encapsulant of the rigid PV segment;
wherein the pre-encapsulated rigid PV segment and the co-located pre-encapsulated flexible PV segment are both further encapsulated by said unified encapsulation layer of the PV hybrid device.

7. The hybrid PV device of claim 1,
wherein said hybrid PV device comprises said rigid PV segment at a first particular device-region that is intended to be maintained non-folded and not-bended;
wherein said hybrid PV device comprises said flexible PV segment at a second particular device-region that is intended to be folded or bended.

8. The hybrid PV device of claim 1,
wherein the rigid PV segment is configured to generate, on average, a first value I1 of electric current;
wherein the flexible PV segment is configured to generate, on average, a second value I2 of electric current;
wherein a difference between I1 and I2 is less than 10 percent of I1;
wherein the rigid PV segment and the flexible PV segment are electrically connected to each other in series due to said difference between I1 and I2.

9. The hybrid PV device of claim 1,
wherein the rigid PV segment is configured to generate, on average, a first value I1 of electric current;
wherein the flexible PV segment is configured to generate, on average, a second value I2 of electric current;
wherein a difference between I1 and I2 is at least 10 percent of I1;
wherein the rigid PV segment and the flexible PV segment are electrically connected to each other in parallel due to said difference between I1 and I2.

10. The hybrid PV device of claim 1,
wherein the hybrid PV device comprises a plurality of co-located PV segments which comprise: a plurality of rigid PV segments and a plurality of flexible PV segments, that are all co-located;
wherein each one of the rigid PV segments is electrically connected, directly or indirectly, to at least one of the flexible PV segments;
wherein each one of the flexible PV segments is electrically connected, directly or indirectly, to at least one of the rigid PV segments.

11. The hybrid PV device of claim 1,
wherein said hybrid PV device comprises a first particular rigid PV segment that is co-located adjacent to a first particular flexible PV segment;
wherein the first particular rigid PV segment is configured to generate, on average, a first value I1 of electric current;
wherein the first particular flexible PV segment is configured to generate, on average, a second value I2 of electric current;
wherein a difference between I1 and I2 is less than 10 percent of I1;
wherein the first particular rigid PV segment and the first particular flexible PV segment are electrically connected to each other in series due to said difference between I1 and I2;
wherein said hybrid PV device comprises a second particular rigid PV segment that is co-located adjacent to a second particular flexible PV segment;
wherein the second particular rigid PV segment is configured to generate, on average, a third value I3 of electric current;
wherein the second particular flexible PV segment is configured to generate, on average, a fourth value I4 of electric current;
wherein a difference between I3 and I4 is less than 10 percent of I3;
wherein the second particular rigid PV segment and the second particular flexible PV segment are electrically connected to each other in series due to said difference between I3 and I4.

12. The hybrid PV device of claim 1,
wherein the hybrid PV device comprises a plurality of co-located PV segments which comprise: a plurality of rigid PV segments and a plurality of flexible PV segments, that are all co-located;
wherein a pair of two co-located PV segments, that generate respectively a first value of average electric current I1 and a second value of average electric current I2, are electrically connected to each other in series if a difference between I1 and I2 is less than N percent of I1, and are electrically connected to each other in parallel if the difference between I1 and I2 is at least N percent of I1; wherein N is a pre-defined threshold value between 0 and 25.

13. The hybrid PV device of claim 1,
wherein at least one of the PV segments comprises:
a silicon wafer, having a plurality of craters that penetrate into the silicon wafer and do not reach a bottom side of the silicon wafer; wherein the plurality of craters assist in mechanical forces absorption and provide resilience to mechanical forces.

14. The hybrid PV device of claim 1,
wherein the rigid PV segment is configured to generate, on average, a first value I1 of electric current;
wherein the co-located flexible PV segment is configured to generate, on average, a second value I2 of electric current;
wherein a difference between I1 and I2 is at least 10 percent of I1;
wherein the rigid PV segment and the co-located flexible PV segment are electrically connected to each other indirectly via a Direct Current to Direct Current (DC/DC) converter unit that converts a level of electric current generated by the rigid PV segment to a level of electric current generated by the flexible PV segment.

15. The hybrid PV device of claim 1,
wherein the rigid PV segment is configured to generate, on average, a first value I1 of electric current;
wherein the co-located flexible PV segment is configured to generate, on average, a second value I2 of electric current;
wherein a difference between I1 and I2 is at least 10 percent of I1;
wherein the rigid PV segment and the co-located flexible PV segment are electrically connected to each other indirectly via a Direct Current to Direct Current (DC/DC) converter unit that converts a level of electric current generated by the flexible PV segment to a level of electric current generated by the rigid PV segment.

16. The hybrid PV device of claim 1
wherein the unified encapsulation layer, which encapsulates together both the rigid PV segment and the co-located flexible PV segment, comprises at least:
a top-side encapsulating layer, which is transparent and enables passage of light therethrough, and is located at a first side of the PV device that is intended to receive incoming illumination for electricity generation;
a bottom-side encapsulating layer, which is non-transparent and blocks passage of light therethrough, and is located at a second side of the PV device that is not intended to receive incoming illumination for electricity generation.

17. The hybrid PV device of claim 1,
wherein the unified encapsulation layer, which encapsulates together both the rigid PV segment and the co-located flexible PV segment, comprises at least:
a top-side encapsulating layer, which is transparent and enables passage of light therethrough, and is located at a first side of the PV device that is intended to receive incoming illumination for electricity generation;
a bottom-side encapsulating layer, which is transparent and enables passage of light therethrough, and is located at a second side of the PV device that is also intended to receive incoming illumination for electricity generation;
wherein the hybrid PV device is a bi-facial PV device or a dual-direction PV device that is capable of receiving incoming light at two opposite sides of the hybrid PV device and converts said incoming light to electricity.

18. The hybrid PV device of claim 1,
wherein the bottom-side encapsulating layer comprises a metal layer that provides structural and mechanical support to said hybrid PV device;
wherein said metal layer is located within said unified encapsulation layer, which encapsulates together both the rigid PV segment and the co-located flexible PV segment.

19. The hybrid PV device of claim 1,
wherein the rigid PV segment is located at a first particular region of the hybrid PV device that is expected to receive a first level of light energy;
wherein the flexible PV segment is located at a second particular region of the hybrid PV device that is expected to receive a second level of light energy that is smaller than said first level of light energy.

20. The hybrid PV device of claim 1,
wherein the unified encapsulation layer, which encapsulates together both the rigid PV segment and the co-located flexible PV segment, comprises:
a first encapsulation layer, which is a transparent top-side unified encapsulation layer that covers a top-side of the rigid PV segment and a top-side of the flexible PV segment;
a second encapsulation layer, which is a non-transparent bottom-side unified encapsulation layer that covers a bottom-side of the rigid PV segment and a bottom-side of the flexible PV segment.

21. The hybrid PV device of claim 1,
wherein the unified encapsulation layer, which encapsulates together both the rigid PV segment and the co-located flexible PV segment, comprises:
a first encapsulation layer, which is a transparent top-side unified encapsulation layer that covers a top-side of the rigid PV segment and a top-side of the flexible PV segment;
a second encapsulation layer, which is a transparent bottom-side unified encapsulation layer that covers a bottom-side of the rigid PV segment and a bottom-side of the flexible PV segment;
wherein the hybrid PV device is a bi-facial PV device or a dual-direction PV device, that is capable of receiving incoming light at two opposite sides of the hybrid PV device and converts said incoming light to electricity.

22. The hybrid PV device of claim 1,
wherein the top-side unified encapsulation layer is formed of one or more materials selected from: polycarbonate, polymethyl methacrylate;
wherein the bottom-side unified encapsulation layer is formed of one or more materials selected from: polycarbonate, polymethyl methacrylate, polyurethane, polyethylene, polypropylene, polyamide, Acrylonitrile Butadiene Styrene (ABS), rubber, plastic, polymer, flexible plastic, flexible polymer, rigid plastic, rigid polymer.

23. The hybrid PV device of claim 1,
wherein the rigid PV segment is pre-encapsulated within a first pre-encapsulation material, separately from the co-located flexible PV segment;
wherein the flexible PV segment is pre-encapsulated within a second pre-encapsulation material, separately from the co-located rigid PV segment;
wherein the first pre-encapsulation material is a material selected from: Polyolefin Elastomer (POE), Thermoplastic Polyurethane (TPU), Thermoplastic Olefin or Thermoplastic Polyolefin (TPO) or olefinic thermoplastic elastomer, Ethylene-vinyl acetate (EVA), poly (ethylene-vinyl acetate) (PEVA);
wherein the second pre-encapsulation material is a material selected from: Polyolefin Elastomer (POE), Thermoplastic Polyurethane (TPU), Thermoplastic Olefin or Thermoplastic Polyolefin (TPO) or olefinic thermoplastic elastomer, Ethylene-vinyl acetate (EVA), poly (ethylene-vinyl acetate) (PEVA).

24. The hybrid PV device of claim 1,
wherein the hybrid PV device comprises a plurality of co-located PV segments which include at least one rigid PV segment and at least one flexible PV segment;
wherein at least a first PV segment of said plurality of co-located PV segments is electrically connected in series to a second PV segment of said plurality of PV segments;
wherein at least a third PV segment of said plurality of co-located PV segments is electrically connected in parallel to a fourth PV segment of said plurality of PV segments.

25. The hybrid PV device of claim 1,
wherein the hybrid PV device comprises a plurality of co-located PV segments which include at least one rigid PV segment and at least one flexible PV segment;
wherein at least a first rigid PV segment of said plurality of co-located PV segments is electrically connected in series to a second flexible PV segment of said plurality of PV segments;
wherein at least a third rigid PV segment of said plurality of co-located PV segments is electrically connected in parallel to a fourth flexible PV segment of said plurality of PV segments.

26. The hybrid PV device of claim 1,
wherein the hybrid PV device is a vehicular component that generates electricity for a vehicle.

27. The hybrid PV device of claim 1,
wherein the hybrid PV device is a rooftop PV solar panel that generates electricity for a venue.
